(19) United States
(12) Patent Application Publication
(10) Pub. No.: US 2012/0261759 A1
(43) Pub. Date: Oct. 18, 2012

(54) Semiconductor device and method for manufacturing the same

(76) Inventors: Huilong Zhu, Poughkeepsie, NY (US); Haizhou Yin, Poughkeepsie, NY (US); Zhijiong Luo, Poughkeepsie, NY (US); Qingqing Liang, Lagrangeville, NY (US)

(21) Appl. No.: 13/379,081

(22) PCT Filed: Jun. 1, 2011
(86) PCT No.: PCT/CN2011/075127

§ 371 Date: Dec. 19, 2011

(30) Foreign Application Priority Data
Sep. 29, 2010 (CN) 201010299028.1

(51) Int. Cl. H01L 29/78; H01L 21/336

(52) U.S. Cl. 257/368; 438/296; 257/E29.255; 257/E21.409

(57) ABSTRACT

A semiconductor device comprising: a semiconductor substrate; an STI embedded into the semiconductor substrate and having at least a semiconductor opening region; a channel region in the semiconductor opening region; a gate stack comprising a gate dielectric layer and a gate conductive layer and located above the channel region; and source/drain regions located on both sides of the channel region, and comprising first seed layers on opposite sides of the gate stack adjacent to the STI, wherein the upper surface of the STI is higher than or sufficiently closed to the upper surface of the gate dielectric layer. The semiconductor device and the method for manufacturing the same can enhance the stress of the channel region so as to improve device performance.

This application is a National Phase application of, and claims priority to, PCT Application No. PCT-CN2011-075127, filed on Jun. 1, 2011, entitled “Semiconductor device and method for manufacturing the same”, which claimed priority to Chinese Application No. 201010299028.1, filed on Sep. 29, 2010. Both the PCT Application and Chinese Application are incorporated herein by reference in their entireties.

### TECHNICAL FIELD

The present invention relates to a semiconductor device and a method for manufacturing the same, and particularly to a Metal-Oxide-Semiconductor Field Effect Transistor (MOSFET) and a method for manufacturing the same, which is provided with enhanced source/drain stressor and self-aligned shallow trench isolation (STI) spacer.

### BACKGROUND ART

During the last decades, the development of integrated circuits has almost strictly followed the famous Moore's Law raised by one of the Intel founders—Gordon Moore: the number of transistors contained in integrated circuits (ICs) will double about every 18 months, while the ICs' performance will also double-enhanced. This is substantially achieved by continually scaling-down of ICs' dimension, particularly of MOSFETs' characteristic dimension, i.e. channel length or gate pitch, which are most frequently used in digital circuits. Together with integration techniques, small-dimension packaging, testable designing and so on, it has enabled the number of ICs built on the same wafer to increase rapidly, and therefore the average ICs' manufacturing cost after packaging and testing has been reduced sharply.

In the ICs' manufacturing, different transistors should be insulated each other. A widely used structure at present is shallow trench isolation (STI) extending into substrate, which is also propitious to common CMOS manufacturing.

Referring to FIG. 1A, it shows a MOSFETs' structure of prior art. The MOSFET's forming process substantially includes: applying mask onto silicon substrate 1 and etching the substrate to form a trench, depositing trench oxide to form STI 2, depositing gate dielectric layer 3 and gate electrode layer 4, forming gate stack structure and source/drain groove by etching, implanting ions to form a source region 5 and a drain region 6, epitaxially growing stressor 7 which will provide a channel region 8 with stress to increase carriers' mobility and thus increase saturation current. However, due to the several processes which the whole device structure will go through after forming STI, e.g. erosively cleaning and forming gate stack structure by etching, the solutions or ions which may erode the dielectric material (oxide, nitride, nitrogen oxide) will also erode the STI oxide. As a result, as show in FIG. 1B, the resulting top of STI 2 will be lower than the top of the stressor 7, so that the stress may be released from the side interface between STI 2 and stressor 7 as illustrated by the two arrows shown in FIG. 1B, resulting in the decreasing of stress provided by the stressor to the both sides of the channel region, which fails to achieve the expected carrier mobility and natively affects the device performance.

Accordingly, there is a need for a novel structure which may efficiently prevent stress lost so as to improve device performance and a method of manufacturing the same.

### SUMMARY OF THE INVENTION

The present invention achieves above-mentioned object by providing a MOSFET with a self-aligned Shallow Trench Isolation (STI) spacer and the method for manufacturing the same.

According to one aspect of the present invention, it provides a semiconductor which includes: a semiconductor device comprising: a semiconductor substrate; an STI embedded into the semiconductor substrate and having at least a semiconductor opening region; a channel region in the semiconductor opening region; a gate stack comprising a gate dielectric layer and a gate conductive layer and located above the channel region; and source/drain regions located on both sides of the channel region, and comprising first seed layers on opposite sides of the gate stack adjacent to the STI, wherein the upper surface of the STI is higher than or sufficiently closed to the upper surface of the gate dielectric layer.

In the present invention, the term “sufficiently closed to the upper surface of the gate dielectric layer” can be defined that the upper surface of the gate dielectric layer is not higher than the upper surface of the STI by over 20 nm. By using such a structure, loss of the source/drain stress can be efficiently prevented.

According to another aspect of the present invention, it provides a method of manufacturing semiconductor, which includes: providing a semiconductor substrate; forming an STI in the semiconductor substrate, wherein at least a semiconductor opening region is formed in the STI; forming a nitride layer above the STI; forming a gate stack and source/drain regions on both sides of the gate stack within the semiconductor opening region, wherein the gate stack includes a gate dielectric layer and a gate conductive layer, the source/drain regions include first seed layers on opposite sides of the gate stack and adjacent to the STI; and removing the nitride layer above the STI; wherein after removing the nitride layer, the upper surface of the STI is higher than or sufficiently closed to the upper surface of the gate dielectric layer. In the present invention embodiment, the term “closed enough to the upper surface of the gate dielectric layer” can be defined that the upper surface of the gate dielectric layer is not higher than the upper surface of the STI by over 20 nm. By using such a method, loss of the source/drain stress can be efficiently prevented.

According to the embodiments of the present invention, the source/drain regions can be defined in the opening region formed by the STI since the upper surface of the STI is higher than or sufficiently closed to the upper surface of source/drain region, which can efficiently increase the stress at both sides of the channel region, thereby increasing the carrier mobility and improving the performance of the semiconductor device.

The embodiments of the present invention can efficiently prevent the stress from releasing out of the opening region especially for the semiconductor structure with a stress layer on the source/drain regions.

The aforesaid object of the present invention and other objects not listed here are fulfilled within the scope of the independent claims according to the present invention. The embodiments of the present invention are defined in the dependent claims.

### BRIEF DESCRIPTION OF THE DRAWINGS

FIG. 1A,1B illustrate a MOSFET structure with a stress layer and an STI according to prior art.

FIG. 2 is a top view of an initial structure including a substrate, an oxide liner, a nitride layer and a photo resist layer in series.

FIG. 3A,3B illustrate the process of sequentially forming the oxide liner, the first nitride layer and the first photo resist layer on the substrate.

FIG. 4A,4B illustrate the process of forming a shallow trench by patterning and etching.

FIG. 5A,5B illustrate the process of depositing and planarizing the STI.

FIG. 6A,6B illustrate the process of etching-back the STI and depositing a second nitride layer.

FIG. 7A,7B illustrate the process of depositing and planarizing a polysilicon layer to stop at the second nitride layer.

FIG. 8A,8B illustrate the process of selectively etching the second nitride layer.

FIG. 9A,9B illustrate the process of removing the polysilicon layer and the oxide liner.

FIG. 10A,10B illustrate the process of depositing an STI spacer.

FIG. 11 illustrates a top view of a middle structure with an active region and a nitride layer.

FIG. 12 illustrates a cross-sectional structure along 11′ direction in FIG. 11 after patterning the second photo resist layer and removing the second nitride layer within the active region.

FIG. 13 illustrates a top view of the spacer structure to be etched.

FIG. 14A,14B illustrate the process of etching the second nitride layer and the STI spacer which are not covered by the second photo resist layer.

FIG. 15 illustrates the process of removing the second photo resist layer to form a gate dielectric layer.

FIG. 16 illustrates the process of forming the gate stack structure.

FIG. 17-19 illustrate the process of forming source/drain regions.

FIG. 20 illustrates a top view of the structure of a metal silicide to be formed.

FIG. 21A,21B illustrate the process of forming the metal silicide and the resulting novel device structure.

FIG. 22,23 illustrate the semiconductor device structure according to another embodiment of the present invention.

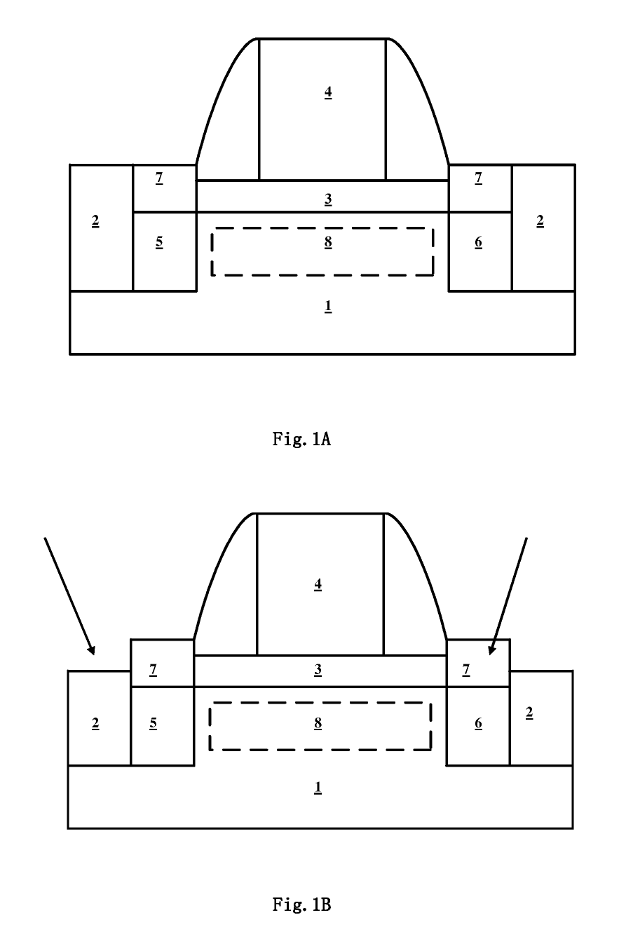

### DETAILED DESCRIPTION

The features and technical effects of the present invention will be described in detail with reference to the drawings and schematic embodiments, disclosing a novel MOSFET with an enhanced source/drain stressor and a self-aligned STI edge protector layer and the method of manufacturing the same. It should be noted that the similar reference numbers denote the similar structure. The terms used in the present invention like “first”, “second”, “up/upon”, “down/low/beneath/under” etc. can be used in denoting various device structures, and do not indicate the relationship in space, sequence or hierarchy of the device structures unless specially illuminated these terms, if not stated otherwise.

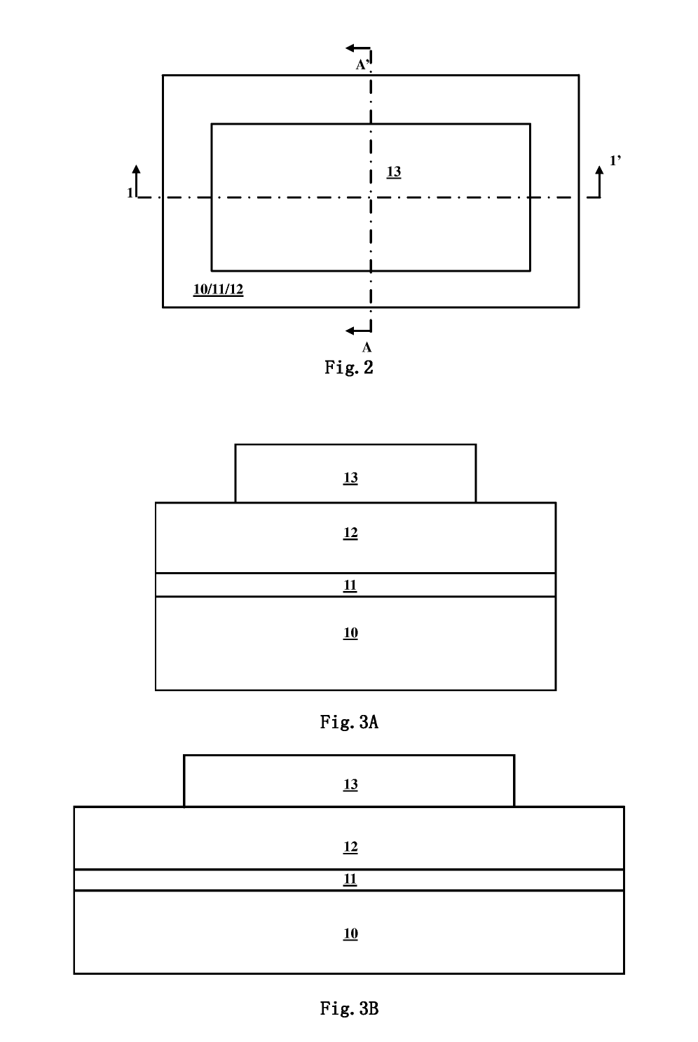

Now referring to FIG. 2 and FIG. 3A,3B, they illustrate the preparative process of manufacturing a MOSFET on a conventional semiconductor substrate, comprising sequentially forming an oxide liner, a first nitride layer and a first photo resist layer on the substrate. FIG. 2 is top view, FIG. 3A is a cross-sectional view along A-A′ line of the structure shown in FIG. 2, and FIG. 3B is a cross-sectional view along 1-1′ line of the structure shown in FIG. 2.

Firstly, an oxide liner 11 is formed on the substrate 10. For example, it not only can be implemented by conventional processes such as APCVD, LPCVD, PECVD etc., but also can be implemented by a thermal oxidation method. By controlling the parameters such as velocity of material flow, temperature, pressure etc., the oxide liner 11 with good property and predetermined thickness can be obtained. The thickness of the oxide liner 11 in the present embodiment may be about 10 to 40 nm, preferably 20 nm. The substrate 10 may be made of bulk silicon or silicon On insulator (SOI), or may be any other appropriate semiconductor compound materials, for example, III-V compound semiconductor materials like GaAs and etc. When the substrate 10 is made of silicon, the formed oxide liner 11 is silicon oxide.

Secondly, a first nitride layer 12 is formed on the oxide liner 11. It can be implemented by conventional depositing processes. The first nitride layer 12 with good property and uniform thickness can be obtained by controlling parameters of depositing. The thickness of the first nitride layer 12 in the present embodiment is about 30 to 150 nm, preferably 60 to 120 nm, and most preferably 90 nm. For a silicon substrate, the formed nitride layer is silicon nitride. The Oxide liner 11 can be used to protect the substrate structure underneath in etching or other processes. The first nitride layer 12 will be used as a mask layer in later etching process of forming STI.

Then, the STIs are patterned. A first photo resist layer 13 is formed on the first nitride layer 12. Then soft-baking is performed at certain temperature. Afterwards, the first photo resist layer 13 is exposed and developed with the mask pattern desired by the STI. After another high temperature processing, a cured first photo resist pattern is formed on the first nitride layer 12 to cover the active region with a plurality of openings corresponding to the STIs formed around the active retion. Referring to FIG. 2, the first photo resist layer 13 is located in the central region, and the stacked structure of the substrate 10/the oxide liner 11/the first nitride layer 12 is located in the peripheral region.

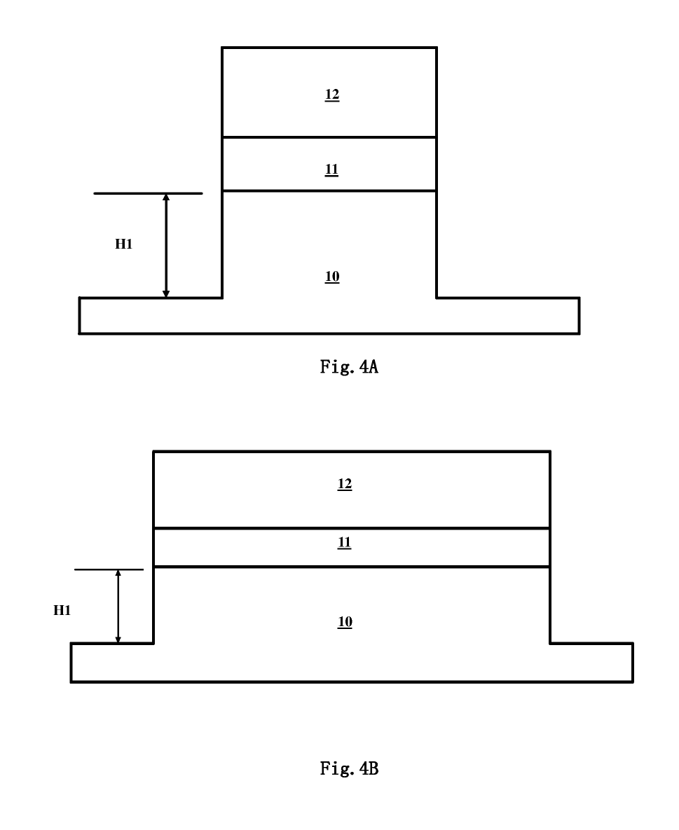

Referring to FIG. 4A,4B, they illustrate the process of forming shallow trench by patterning and etching. FIG. 4A is a cross-sectional view along A-A′ line of the structure shown in FIG. 3A after etching and photo resist removing, and FIG. 4B is a cross-sectional view along 1-1′ line of the structure shown in FIG. 3B after etching and photo resist removing. Similarly, FIG. A corresponds to a cross-sectional view along A-A′ line of the structure, and FIG. B corresponds to a cross-sectional view along 1-1′ line of the structure.

Then the shallow trench is formed by etching. The STI structure can be made by conventional processes. Due to the small device dimension and complex structure, anisotropic dry-etching is typically used in order to control precision of device structure, particularly the verticality of STIs so as to avoid over-etching in active region. RIE is preferably used in the present embodiment. Types and flow rate of etchant gases can be appropriately adjusted according the types of the etched materials and the device structure. Referring to FIG. 4A and FIG. 4B, the oxide liner 11 and the first nitride layer 12 in the STI region are completely etched off to expose the substrate 10. And trenches are formed by further etching into the substrate 10. The depth H1 of the trench extending into substrate 10 is defined as the distance from the lower surface of the trench to the upper surface of the substrate 10 (i.e. the interface between the substrate 10 and the oxide liner 11). The depth H1 in the present embodiment is about 100 to 500 nm, and preferably about 150 to 350 nm.

Afterward, the first photo resist layer 13 is removed by well-known methods in the art.

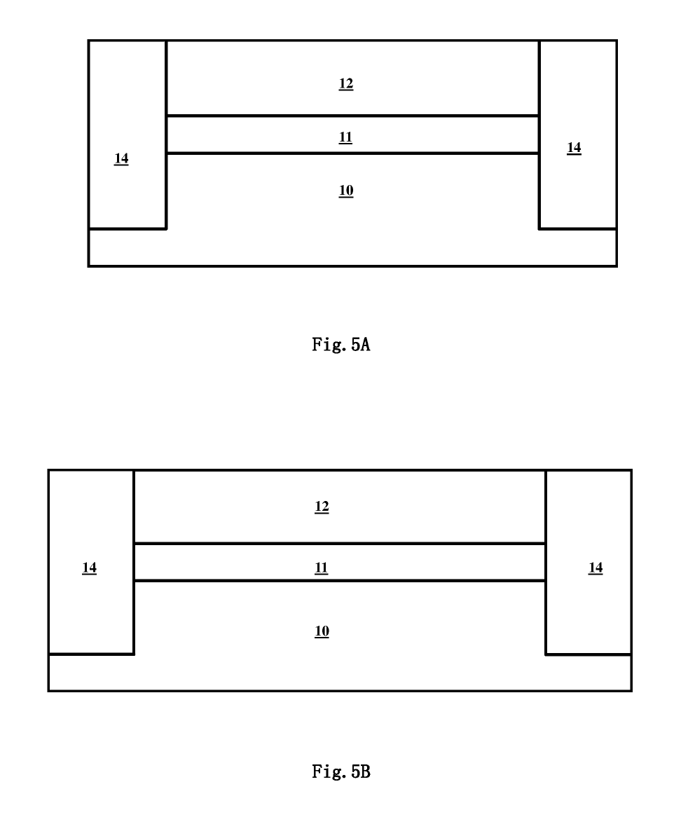

Referring to FIG. 5A and FIG. 5B, which illustrate the process of depositing and planarizing the STI. In the process, STI oxide 14 is firstly deposited in the shallow trench. Similar to formation of the oxide liner, the STI oxide 14 can be formed by conventional processes, and is typically made of SiO₂. Preferably, after the depositing of the STI oxide 14, Chemical-Mechanical Polishing (CMP) is performed to planarize the upper surface of STI oxide 14 to expose the top of first nitride layer 12 with the first nitride layer 12 being used as a stop layer.

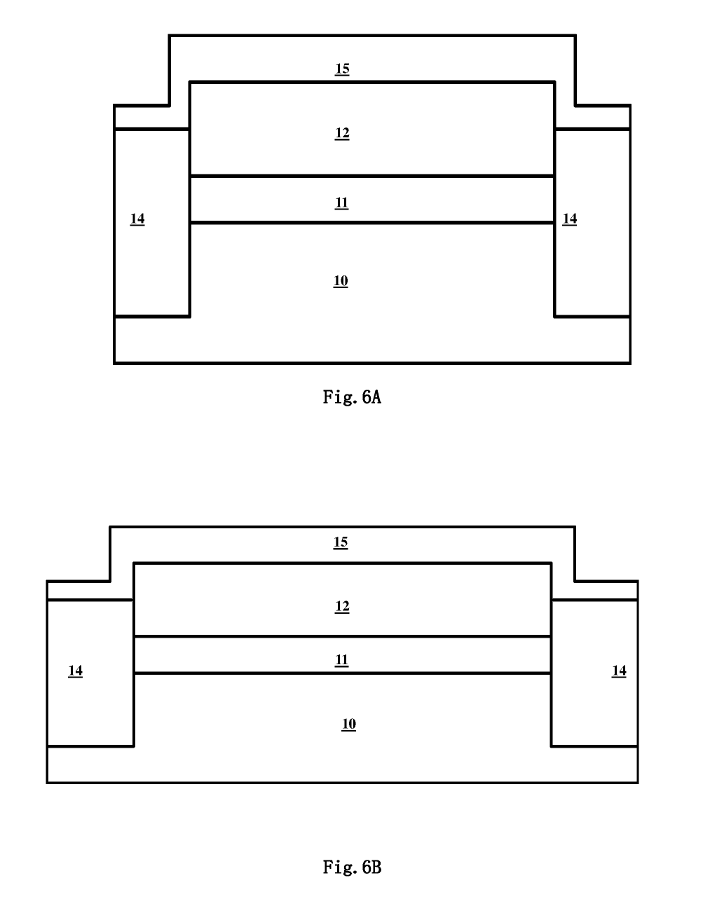

FIG. 6A and FIG. 6B illustrate the process of etching-back STI and depositing a second nitride layer.

Then, the STI oxide 14 is etched back. The STI oxide 14 is etched by using the similar process of forming the STI trench by etching, which enables the upper surface of the STI oxide 14 lower than that of the first nitride layer 12 and higher than that of the semiconductor substrate 10 so as to form multiple trenches.

Then, the second nitride layer 15 is formed on the entire top surface of the device by methods such as High-Density Plasma Chemical Vapor Deposition (HDPCVD) or other methods. HDPCVD enables the thickness of the second nitride layer 15 formed on sidewalls of the first nitride layer 12 to be smaller than that of the second nitride layer 15 formed on top of both the first nitride layer 12 and STI oxide 14. In this embodiment, the thickness of the second nitride layer 15 formed on the sidewalls of the first nitride layer 12 is about 7 to 10 nm, and the thickness of the second nitride layer 15 formed on top of the first nitride layer 12 is about 20 to 30 nm.

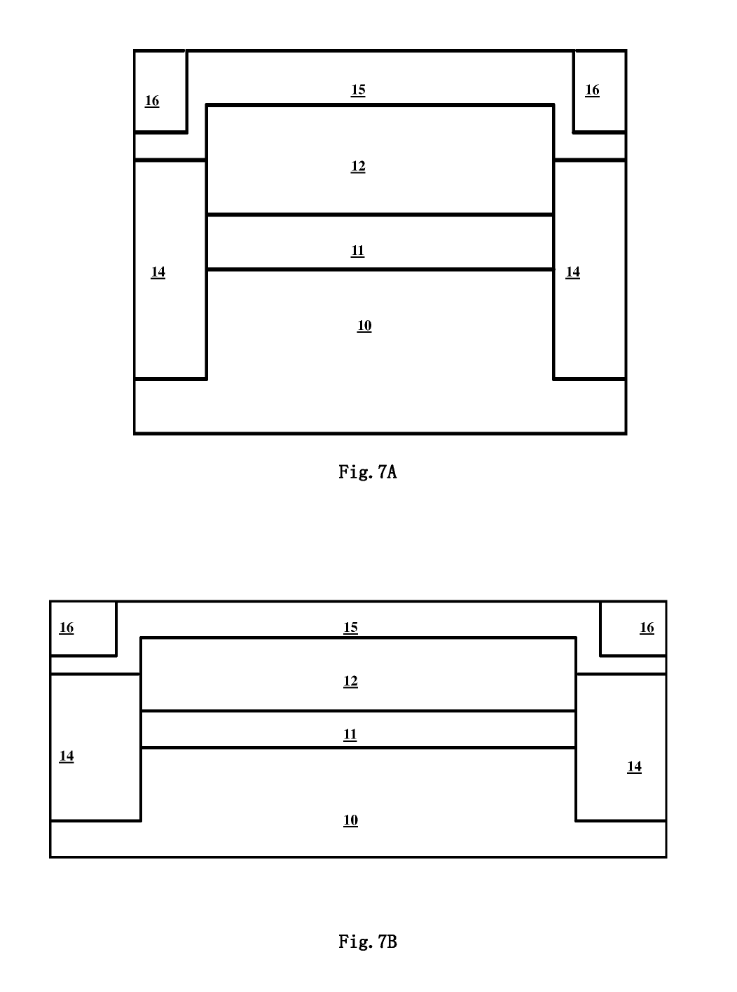

FIG. 7A and FIG. 7B illustrate the processes of depositing and planarizing a polysilicon layer 16 to expose the second nitride layer. Specifically, polysilicon can be deposited on the entire device surface by conventional CVD or other methods, and then CMP is performed to stop at the upper surface of the second nitride layer 15, so that only the polysilicon layer 16 remains on the STI trenches.

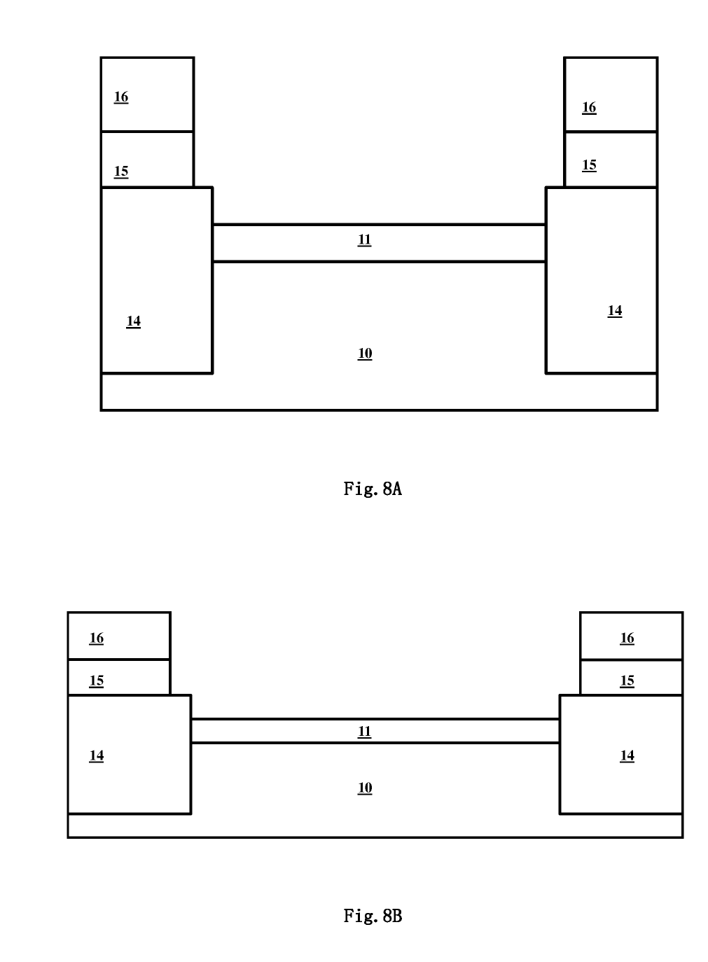

FIG. 8A and FIG. 8B illustrate the process of selective etching of the second nitride layer 15. The nitride layer is selectively etched by Reactive Ion Etching (RIE). By selecting the reactive ions and etching conditions, the etching speed of the nitride is higher than that of the polysilicon and oxide, so that the first nitride layer 12 and the second nitride layer 15 within the opening formed between the STIs 14 are completely etched, while only the second nitride layer 15 under the polysilicon layer 16 remaining and the oxide liner being exposed 11.

Because the thickness of the second nitride layer 15 on the sidewall of the first nitride layer 12 is smaller than that on top of the first nitride layer 12, the nitride on the STI 14 is not etched in this etching process. The surface of the STI can't be easily damaged in later cleaning or etching processes due to the protection of the nitride on the STI 14.

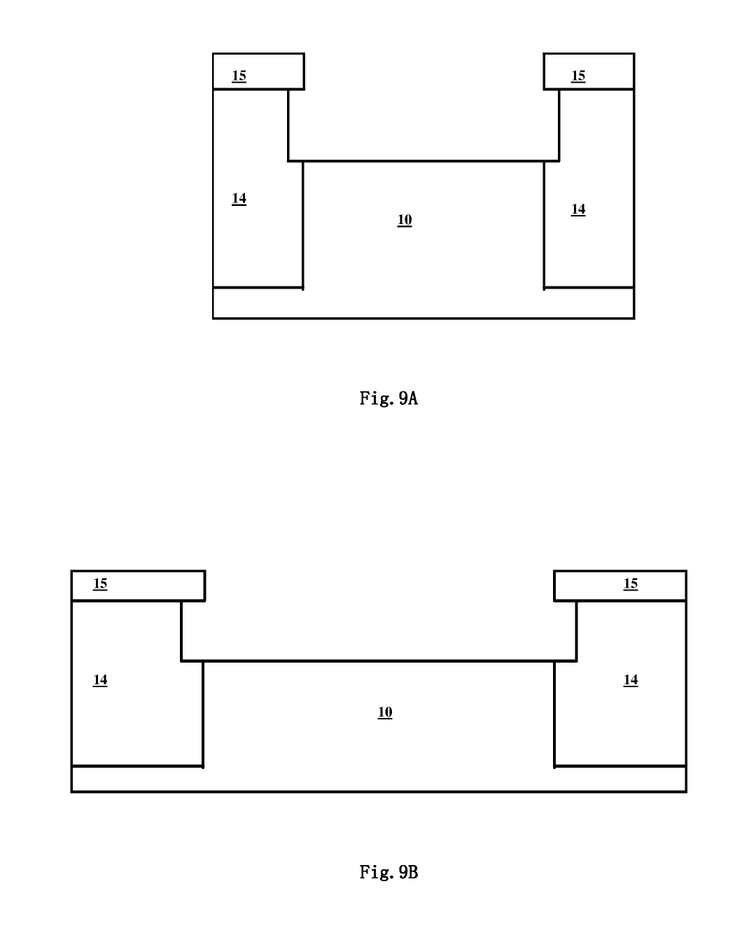

FIG. 9A and FIG. 9B illustrate the process of removing the polysilicon layer 16 and the oxide liner 11. Both the polysilicon on the second nitride layer 15 and the oxide liner 11 lower than the second nitride layer 15 can be removed by an isotropic dry-etching or wet-etching method. The resulting structure is shown in FIG. 9A and FIG. 9B.

Because of protection provided by the nitride on the STI 14, the erosion to the STI 14 caused by cleaning or etching will be greatly suppressed in later processes, so as to keep the STI with appropriate height.

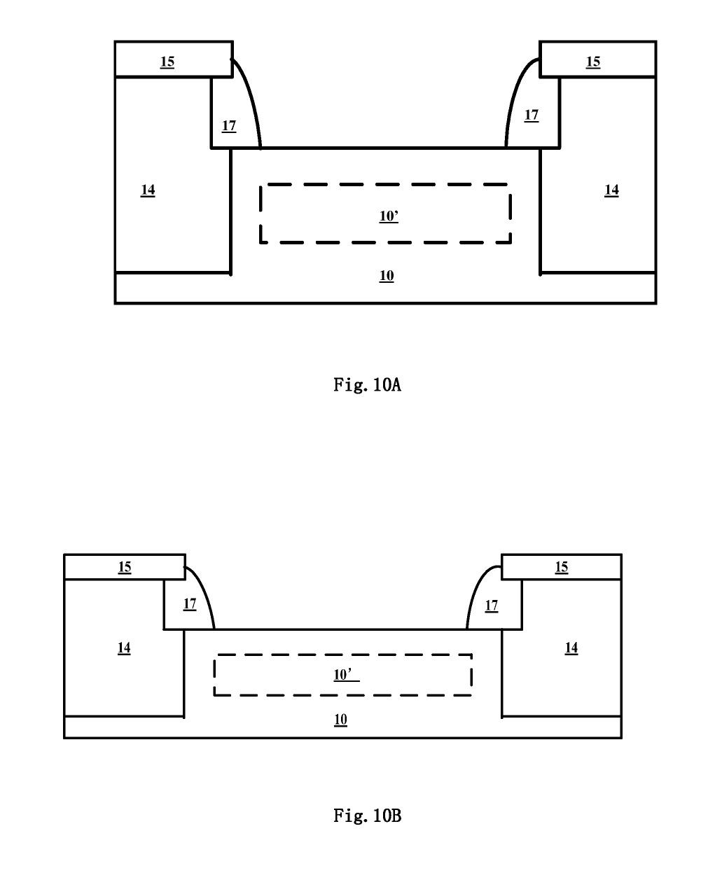

FIG. 10A and FIG. 10B illustrate the process of forming an STI spacer 17. First, a thin oxide layer (not shown in the figures) is formed by, e.g., depositing to have a thickness of about 2 to 5 nm. The thin oxide layer may be used as a stop layer in later formation of the STI spacer by RIE. Then the third nitride layer is deposited by conventional processes to have a thickness of about 5 to 30 nm. Afterwards, the third nitride layer is etched by RIE to form the STI spacer 17 on sidewalls of the STI 14 and at least partially on the active region 10′. The STI spacer 17 is self-aligned with the edge of the STI and around the inner walls of the opening, so as to avoid distortion of the patterns caused by alignment deviation of the mask. As shown in FIG. 10A and FIG. 10B, the active region 10′ is indicated by dashed lines in the substrate 10.

Optionally, the STI spacer 17 in the channel region may be removed.

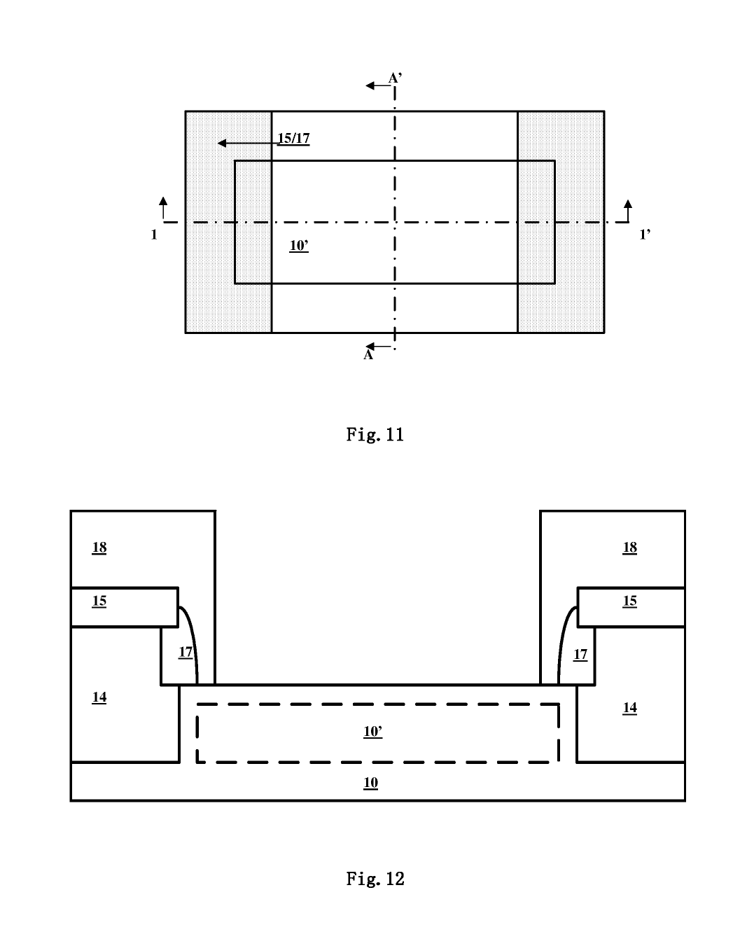

FIG. 11 and FIG. 12 illustrate the process of patterning a second photo resist layer 18 to remove the second nitride layer 15 within the active region. FIG. 11 is a top view with the second nitride layer 15 and STI spacer 17 indicated by the dotted areas. The central active region 10′ is partially overlapped with the STI spacer 17. FIG. 12 is a cross-sectional view along 11′ direction of the structure shown in FIG. 11. Similar to formation of the first photo resist layer 13, the second photo resist 18 layer is coated on the dotted areas shown in FIG. 11, then is soft-baked at certain temperature, and is exposed and developed. After another high temperature processing, the second photo resist layer 18 is only kept on the second nitride layer 15, the STI spacer 17 and part of the substrate 10, as shown in FIG. 12.

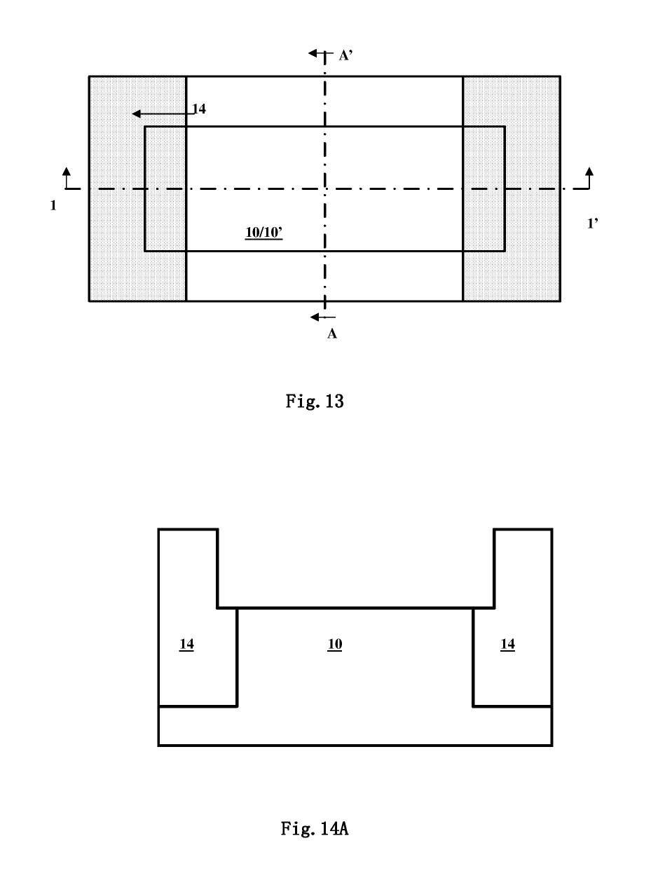

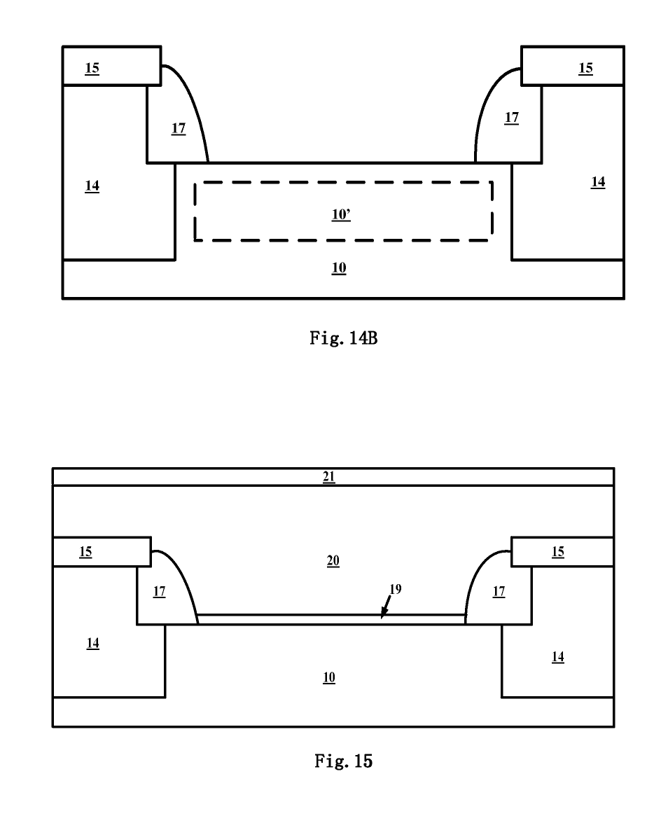

FIGS. 13,14A and 14B illustrate the process of etching the second nitride layers 15 and the STI spacer 17 which are not covered by the second photo resist layer 18. The nitride can be etched by conventional methods. Because there does not exist the second photo resist layer 18 along the A-A′ direction in the top view of FIG. 13, the top surface of the STI oxide 14 is exposed, and the STI spacer 17 is removed, so that the substrate 10 is completely exposed in this direction, as shown in FIG. 14A. However, because there partially exist the second photo resist layer 18 along the 1-1′ direction in FIG. 13, the structure shown in FIG. 14B is formed in such a way that a part of the second nitride layer 15 and a part of the STI spacer 17 is kept.

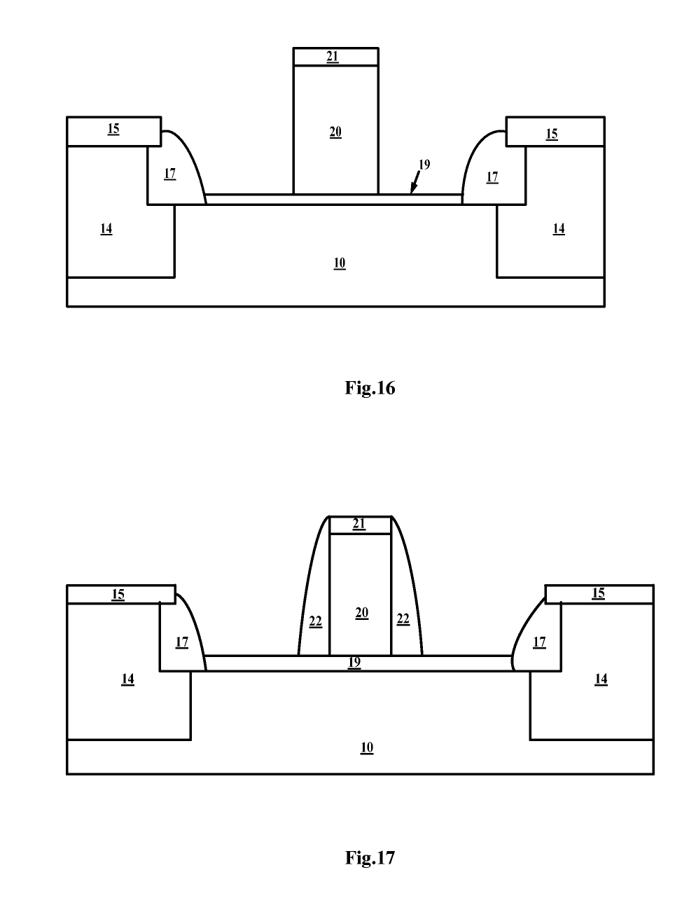

FIG. 15 is a cross-sectional view along line 1-1′ illustrating the process of forming gate dielectric layers after removing the second photo resist layer. FIG. 16 illustrates the process of forming a gate stack structure.

Specifically, a gate dielectric layer 19 is firstly formed on the surface of the entire device structure. The gate dielectric layer 19 may be a normal gate dielectric layer or a high-k gate dielectric layer having a thickness of about 1 to 3 nm. Metal layers (not shown) can be deposited on the gate dielectric layer 19 to have a thickness of about 10 to 20 nm as a gate conductive layer. Then the polysilicon layer 20 with a thickness of about 20 to 50 nm is deposited on the gate metal layers. The fourth nitride layer 21 with a thickness of about 10 to 40 nm is deposited on the polysilicon layer 20. Afterwards, a gate pattern is formed by patterning the third photo resist layer (not shown). The polysilicon layer 20 and the gate metal layers are etched by conventional processes such as RIE to the fourth nitride layer 21 to expose the gate dielectric layer 19, so that the gate stack structure shown in FIG. 16 is formed.

In the semiconductor device formed in the embodiment of the present invention, the STI is typically higher than or closed enough to the upper surface of gate the dielectric layer 19. The term “closed enough’ means that even if the upper surface of the gate dielectric layer 19 is higher than that of the STI, the height difference is not more than 20 nm. However, in a semiconductor device formed by conventional processes, the upper surface of the STI is typically lower than that of the gate dielectric layer by at least 60 nm.

FIG. 17 is a cross-sectional view along line 1-1′ illustrating the process of forming source/drain regions. Firstly, according to practical requirements, the source/drain regions having halo regions and extension structures (not shown) are formed by ion plantation, so as to adjust the threshold voltage and to prevent punching through of source and drain. Then, gate spacers which are different from the STI spacers are formed on sidewalls of the gate stack structure. The forming of the gate stack structure includes: depositing a thin oxide layer (not shown) with a thickness of about 2 to 5 nm as a stop layer on the entire structure, then depositing a fifth nitride layer 22 with a thickness of about 10 to 50 nm, and etching the fifth nitride layer 22 by RIE to form the gate spacers 22 on the gate sidewalls.

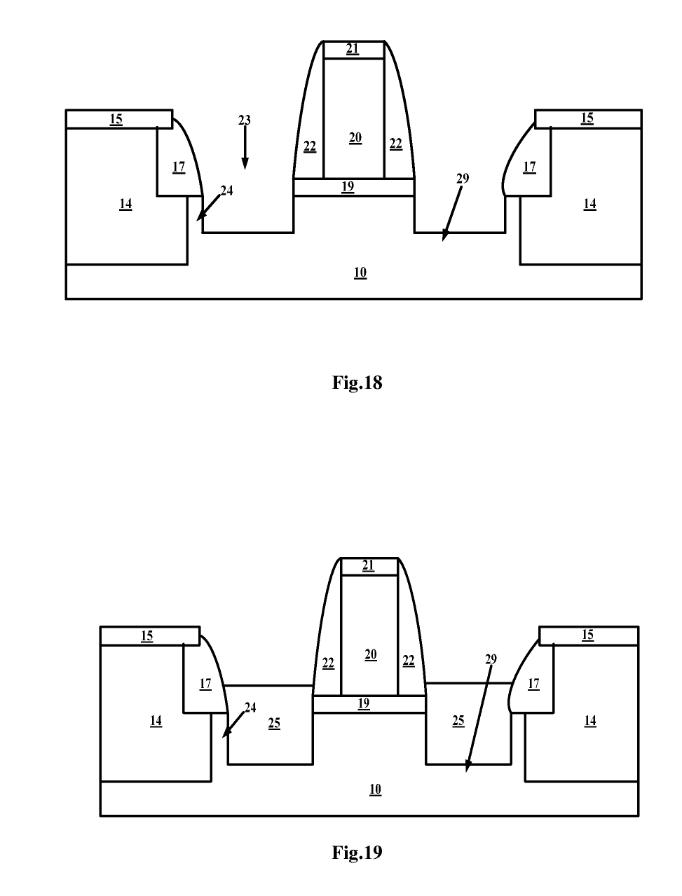

FIG. 18 is a cross-sectional view along line 1-1′ illustrating the process of etching the substrate 10 within the boundary of the STI spacer 17 and the gate spacer 22 to form groove 23 for forming source/drain regions. The substrate material in source/drain regions is etched off by RIE. Due to the STI spacer 17 and the gate spacer 22 above source/drain regions, parameters for RIE can be adjusted to control the selectivity ratio between the substrate silicide and the nitride spacer so as to form the grooves 23 in the substrate shown in FIG. 15. As shown in FIG. 15, there is a gap between the grooves 23 and the STI 14 due to the existence of the STI spacer 17. The gap serves as a first seed layer 24 for forming source/drain stressors in later processes, and may have a width preferably of about 5 to 20 nm.

Optionally, dopants for the source/drain regions may be implanted into the substrate under the grooves. For example, for a pMOSFET, the dopants may be boron ions; and for an nMOSFET, the dopants may be phosphor or arsenic ions. Herein, the portion of the substrate adjacent to the bottom of the groove may be referred as the second seed layer 29.

FIG. 19 is a cross-sectional view along line 1-1′ illustrating the process of forming the stressed source/drain regions. The stressor 25 is formed by selectively epitaxially growing to adjust the stress of the channel region for improving the device performance. Specifically, the first seed layer 24 and the second seed layer 29 on the bottom of the grooves 23 are used as a seed for epitaxially growing the stressor 25. For a pMOSFET, the material of the stressor may be SiGe, so as to apply compressive stress to the channel region. The content of Ge may be about 15% to 70%. For an nMOSFET, the material of the source/drain regions may be Si:C, so as to apply tensile stress to the channel region. The content of C may be about 0.2% to 2%. The source/drain regions are formed from the first seed layer 24, the second seed layer 29 and the stressor 25 on the second seed layer 29. Because the first seed layer 24 is also used as a seed for epitaxially growing crystal, the growing of the stressor is much easier.

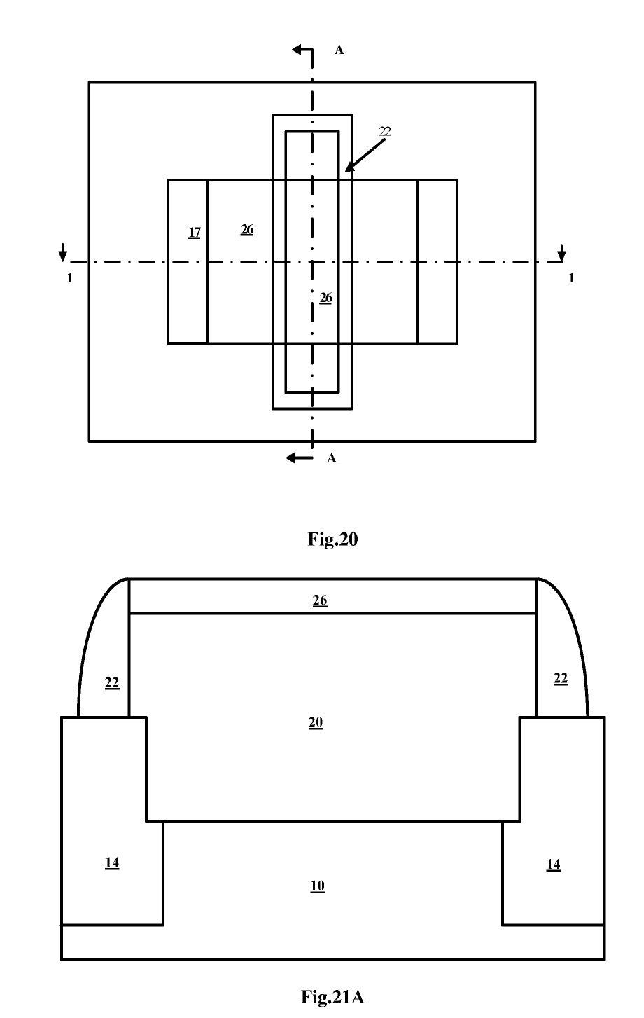

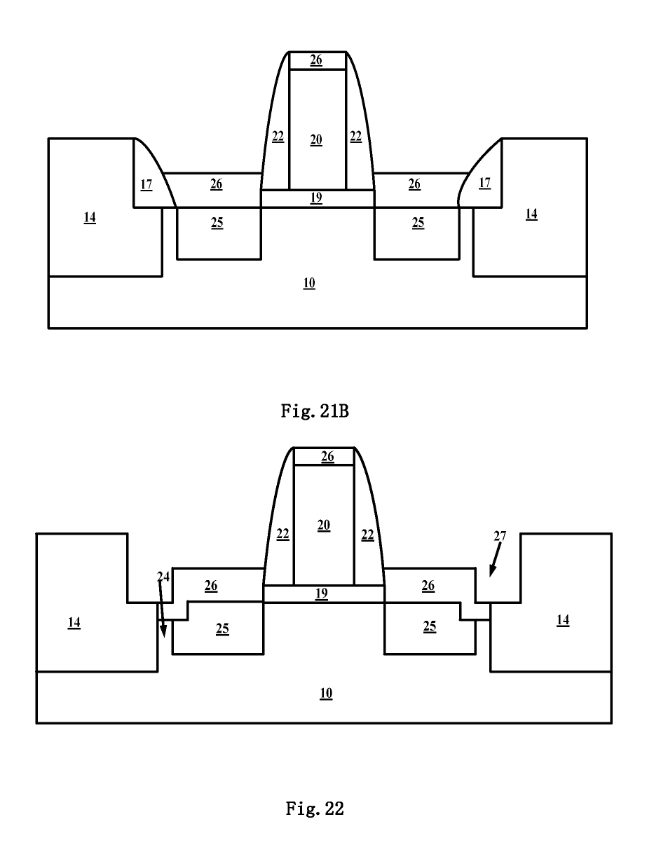

FIG. 20, FIG. 21A and FIG. 21B are a top view, a cross-sectional view along line A-A′ and a cross-sectional view along line 1-1′ illustrating the process of forming the mental silicide 26, respectively. The second nitride layer 15 and the fourth nitride layer 21 are removed by RIE to expose the top of gate stack, i.e. to expose the polysilicon layer 20. Then the metal silicide 26, for example, SiPtNi, is formed on the source/drain regions and on the polysilicon layer 20 by conventional methods, e.g. firstly forming a thin layer of NiPt by sputtering, performing rapid annealing to form silicide SiPtNi at a temperature of about 300-500° C., removing unreacted metals by selectively wet etching, and then performing another rapid annealing to form low-impedance silicide 26 as the metal silicide.

Thus, the semiconductor device shown in FIG. 21B according to one embodiment of the present invention is formed. The semiconductor device comprises: a semiconductor substrate 10; an STI 14 embedded into the semiconductor substrate 10 with at least one semiconductor opening region; a channel region within the opening region; a gate stack having a gate dielectric layer 19 and a gate conductive layer 20 and located above the channel region; and source/drain regions located at both sides of the channel and having first seed layers 24 at opposite sides of the gate stack and adjoining to the STI, wherein the upper surface of STI 14 is higher than or sufficiently closed to the upper surface of the gate dielectric layer 19.

In embodiment of the present invention, the term “sufficiently closed to the upper surface of the gate dielectric layer” can be defined that the height difference is not over 20 nm even if the upper surface of the gate dielectric layer 19 is higher than that of the STI. However, in the semiconductor device formed by conventional processes, the upper surface of the STI is typically lower than that of the gate dielectric layer by over 60 nm. Therefore, loss of the source/drain stress can be efficiently prevented by the processes of the present invention.

In addition, the gate stack structure preferably further comprises the gate metal silicide 26 and the gate spacers 22 surrounding sidewalls of the gate stack structure.

Preferably, the STI spacer 17 is self-aligned with the edge of the STI 14 and at least partially located in the active region 10″, and most preferably at least partially located in the source/drain regions.

The source/drain regions are formed of the first seed layer 24, the second seed layer 29 and the stressor 25 on the second seed layer 29. The second seed layer 29 is located at bottom of the source/drain regions, the stressor 25 is formed by epitaxially growing the first seed layer 24 and the second seed layer 29. Preferably, the second seed layer 29 may contain in-situ doped ions. For example, for a pMOSFET, the ions can be boron, and for an nMOSFET, the ions can be phosphor or arsenic. Preferably, for a pMOSFET, materials of the stressor may be SiGe in order to apply compressive stress to the channel region, and the content of Ge may be about 15% to 70%. For an nMOSFET, the material of source/drain regions may be Si:C in order to apply tensile stress to the channel region, and the content of C is about 0.2% to 2%.

Preferably, metal silicide 26 may be formed on source/drain regions to be respectively adjacent to the STI spacer 17 and the gate spacer 22. The STI spacer 17 can be formed by any one of or combinations of SiO₂, Si₃N₄, and SiON.

Preferably, the thickness of the first seed layer between the source/drain regions 25 and the STI 14 may be 5 to 20 nm, which is advantageous for epitaxially growing the stressor.

Preferably, the upper surface of the STI 14 is higher than that of the gate dielectric layer 19.

In an embodiment of the present invention, the upper surface of the STI is higher than or sufficiently closed to the upper surface of the gate dielectric layer. Therefore, loss of source/drain stress may be suppressed, thererby improving the channel stress and the carrier mobility, which in turn may enhance device performance.

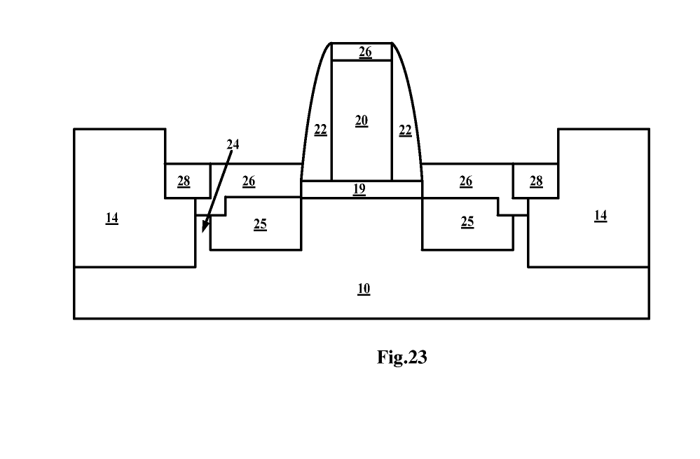

FIGS. 22 and 23 illustrate a semiconductor device structure according to another embodiments of the present invention. The manufacturing method of this embodiment is the same with the aforementioned embodiment, except that in this embodiment, after the step of forming stressed source/drain regions and prior to the step of forming the metal silicide 26, not only the second nitride layer 15 and the fourth nitride layer 21 are removed by RIE to expose top of the gate stack structure, i.e. to expose the polysilicon layer 20, but also the STI spacer 17 is processed by RIE to ensure that there is no nitride spacer remained on sidewall of the STI 14. Since the ions in the RIE process also act on the source/drain stressor 25, grooves may be formed in the source/drain regions 25 near the side where the STI spacer 17 was located before it is removed. Accordingly, in later step of forming the metal silicide 26, grooves 27 may also be formed to correspond to the source/drain regions 25 in the metal silicide 26 at the side where the STI spacer 17 is located, as shown in FIG. 22. In later processrs, e.g. depositing interlayer dielectric layers or other insulator layers, the grooves 27 will be filled with dielectric material.

Accordingly, in one embodiment of the present invention, the STI 14 and the source/drain regions 25 are preferably isolated above the first seed layer 24 by the dielectric material 28, as shown in FIG. 23. The dielectric material 28 may include any of or any combination of SiOF, SiCOH, SiO, SiCO, SiCON, PSG, and BPSG.

Preferably, the metal silicide 26 is located on top of the source/drain stressor 25, and thus the dielectric material 28 is located between the metal silicide 26 and the STI 14.

Although the present invention is descried with one or more exemplary embodiments, one skilled in the art will recognize that various appropriate changes and equivalents of the device structures can be made without departing from the scope of the present invention. Furthermore, a great deal of modifications of specific situation or materials can be made to the disclosed enlightenment without departing from the scope of the present invention. Thus, the intent of the present invention is not limited to the disclosed illustrative examples for implementing the best embodiments. The disclosed device structures and the method of manufacturing the same will include all the exemplary embodiments within the scope of the invention.

1. A semiconductor device comprising:
a semiconductor substrate;
an STI embedded into the semiconductor substrate and having at least a semiconductor opening region;
a channel region in the semiconductor opening region;
a gate stack comprising a gate dielectric layer and a gate conductive layer and located above the channel region; and
source/drain regions located on both sides of the channel region, and comprising first seed layers on opposite sides of the gate stack adjacent to the STI,
wherein the upper surface of the STI is higher than or sufficiently closed to the upper surface of the gate dielectric layer.

2. The semiconductor device according to claim 1, wherein above the first seed layer, the STI and the source/drain region are isolated by dielectric materials.

3. The semiconductor device according to claim 2, wherein the dielectric materials include any one or combinations of SiOF, SiCOH, SiO, SiCO, SiCON, PSG, and BPSG.

4. The semiconductor device according to claim 2, wherein metal silicide is formed on top of the source/drain regions, and the dielectric materials are located between the metal silicide and the STI.

5. The semiconductor device according to claim 1, wherein STI spacers are formed on the first seed layer, and the STI spacers are self-aligned with sidewall of the STI and at least partially located in the source/drain regions.

6. The semiconductor device according to claim 5, wherein the STI spacer is formed from any one or combinations of SiO2, Si3N4, and SiON.

7. The semiconductor device according to claim 1, wherein the thickness of the first seed layer is about 5 to 20 nm.

8. The semiconductor device according to claim 1, wherein the source/drain regions further includes a stressor and a second seed layer, and wherein the stressor is located between the gate stack and the first seed layer, and the second seed layer is located under the stressor.

9. The semiconductor device according to claim 8, wherein the stressor includes epitaxially grown SiGe for a pMOSFET, or epitaxially grown Si:C for an nMOSFET.

10. A method of manufacturing a semiconductor device, comprising:
providing a semiconductor substrate;
forming an STI in the semiconductor substrate, wherein at least a semiconductor opening region is formed in the STI;
forming a nitride layer above the STI;
forming a gate stack and source/drain regions on both sides of the gate stack within the semiconductor opening region, wherein the gate stack includes a gate dielectric layer and a gate conductive layer, the source/drain regions include first seed layers on opposite sides of the gate stack and adjacent to the STI; and
removing the nitride layer above the STI;
wherein after removing the nitride layer, the upper surface of the STI is higher than or sufficiently closed to the upper surface of the gate dielectric layer.

11. The method according to claim 10, wherein the step of forming an STI in the semiconductor substrate comprises:
forming an oxide liner on the semiconductor substrate;
forming a first nitride layer on the oxide liner;
forming an STI groove by etching the oxide liner, the first nitride layer and the semiconductor substrate at the location where the STI will be formed;
forming dielectric materials in the STI groove; and
planarizing the dielectric materials to expose the first nitride layer.

12. The method according to claim 11, wherein the nitride layer includes a second nitride layer, and the step of forming a nitride layer above the STI comprises:
etching-back the STI to under the upper surface of the first nitride layer;
forming a second nitride layer on the first nitride layer;
forming a polysilicon layer on the second nitride layer;
planarizing the polysilicon layer to expose the upper surface of the second nitride layer;
covering the polysilicon layer above the STI with a photo resist layer, and etching the first nitride layer and the second nitride layer within the opening region to expose the oxide liner; and
removing the polysilicon layer.

13. The method according to claim 12, wherein the second nitride layer is formed by HDPCVD.

14. The method according to claim 10, wherein before the step of forming the gate stack and the source/drain regions on both sides of the gate stack, the method further comprises:
forming an STI spacer by self-aligning sidewalls of the STI, wherein the STI spacer is at least partially located in the source/drain regions.

15. The method according to claim 14, wherein the step of forming an STI spacer comprises:
depositing an oxide layer and a third nitride layer; and
selectively etching the third nitride layer and the oxide layer to form the STI spacer on sidewalls of the STI.

16. The method according to claim 14, wherein the step of forming the gate stack comprises:
forming a gate dielectric layer in the opening region;
forming a gate conductive layer on the gate dielectric layer;
etching the gate conductive layer to form the gate stack; and
forming a gate spacer surrounding the gate stack.

17. The method according to claim 15, wherein the step of forming the source/drain regions comprises:
etching downwards the gate dielectric layer and the semiconductor substrate to form a source/drain groove within the boundary of the gate spacer and the STI spacer; and
epitaxially growing a stressor with the sidewall of the source/drain groove adjacent to the STI as a first seed layer and the bottom of the source/drain groove as a second seed layer.

18. method according to claim 17, wherein the stressor is formed of SiGe for a pMOSFET, or Si:C for an nMOSFET.

19. The method according to claim 14, wherein after the step of forming the STI spacer, the method further comprises:
removing the STI spacer adjacent to the STI along the width direction of the gate stack.

20. The method according to claim 14, wherein after the step of forming the source/drain regions, the method further comprises:
removing the STI spacer.
